(19) United States
(12) Patent Application Publication
(10) Pub. No.: US 2015/0079727 A1
(43) Pub. Date: Mar. 19, 2015

(54) Amorphous IGZO Devices and Methods for Forming the Same

(71) Applicant: Intermolecular, Inc., San Jose, CA (US)

(72) Inventors: Mankoo Lee, Fremont, CA (US); Charlene Chen, San Jose, CA (US); Tony P. Chiang, Campbell, CA (US); Dipankar Pramanik, Saratoga, CA (US)

(73) Assignee: Intermolecular, Inc., San Jose, CA (US)

(21) Appl. No.: 14/029,713

(22) Filed: Sep. 17, 2013

(51) Int. Cl. H01L 29/66

(52) U.S. Cl. CPC H01L 29/6675
USPC 438/104

(57) ABSTRACT

Embodiments described herein provide improvements to indium-gallium-zinc oxide devices, such as amorphous IGZO thin film transistors, and methods for forming such devices. A relatively thin a-IGZO channel may be utilized. A plasma treatment chemical precursor passivation may be provided to the front-side a-IGZO interface. High-k dielectric materials may be used in the etch-stop layer at the back-side a-IGZO interface. A barrier layer may be formed above the gate electrode before the gate dielectric layer is deposited. The conventional etch-stop layer, typically formed before the source and drain regions are defined, may be replaced by a pre-passivation layer that is formed after the source and drain regions are defined and may include multiple sub-layers.

### TECHNICAL FIELD

The present invention relates to indium-gallium-zinc oxide (IGZO) devices, such as amorphous IGZO (a-IGZO) thin film transistors (TFTs). More particularly, this invention relates to improved IGZO devices and methods for forming such devices.

### BACKGROUND OF THE INVENTION

Amorphous IGZO (a-IGZO) thin-film transistors (TFTs) have attracted a considerable amount of attention due to the associated low cost, room temperature manufacturing processes with good uniformity control, high mobility (e.g., greater than 10 cm²/V*s) for high speed operation, and the compatibility with transparent, flexible, and light display applications. Due to these attributes, a-IGZO TFTs may even be favored over low cost amorphous silicon (a-Si) TFTs and relatively high mobility (e.g., greater than 100 cm²/V*s) polycrystalline silicon (poly-Si) TFT for display device applications.

Recently, attempts have been made to improve the performance of a-IGZO TFTs for advance logic and memory applications to meet future demands. However, despite the superiority for certain applications, a-IGZO TFT performance strongly depends on a-IGZO material formation and other physical aspects. These characteristics may be related to the tail and deep trap states within the band gap (E_{g}) of the a-IGZO channel (or active) layer. These trap states are also correlated to and/or interacted with the concentration of oxygen vacancies to determine an effective doping concentration, the surface passivation at the interfaces between a-IGZO channel layer and the gate or etch-stop dielectrics, and the selection of the source/drain (S/D) contact material. Additionally, due to the interaction of these trap states with the potentially generated charges from light injection and bias stress, the device performance and reliability may be an issue under the negative bias illumination stress (NBIS) condition. It is desirable to address these issues with, for example, advances in manufacturing processes and component design.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above;

FIG. 2 is a cross-sectional view of the substrate of FIG. 1 with a gate electrode barrier layer formed above the gate electrode;

FIG. 3 is a cross-sectional view of the substrate of FIG. 2 with a gate dielectric layer formed above the gate electrode barrier layer and the substrate;

FIG. 4 is cross-sectional view of the substrate of FIG. 3 with an interfacial dielectric layer formed above the gate dielectric layer;

FIG. 5 is a cross-sectional view of the substrate of FIG. 4 with an a-IGZO channel layer formed above the interfacial dielectric layer;

FIG. 6 is a cross-sectional view of the substrate of FIG. 5 with an etch-stop layer formed above the IGZO channel layer;

FIG. 7 is a cross-sectional view of the substrate of FIG. 6 with source and drain regions formed above the etch-stop layer;

FIG. 8 is a cross-sectional view of the substrate of FIG. 7 with a passivation layer formed above the source and drain regions;

FIG. 9 is a cross-sectional view of the substrate taken along line 9-9 in FIG. 8;

FIG. 10 is a cross-sectional view of a substrate with a gate electrode, a gate dielectric layer, and an a-IGZO channel layer formed above, according to some embodiments of the present invention;

FIG. 11 is cross-sectional view of the substrate of FIG. 10 with source and drain regions formed above the IGZO channel layer;

FIG. 12 is a cross-sectional view of substrate of FIG. 11 with a pre-passivation layer formed above the IGZO channel layer and between the source and drain regions;

FIG. 13 is a cross-sectional view of the substrate of FIG. 12 with a passivation layer formed above the source and drain regions;

FIG. 14 is a cross-sectional view of the substrate taken along line 14-14 in FIG. 13; and

FIG. 15 is a block diagram illustrating a method for forming an IGZO device according to some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide improvements to indium-gallium-zinc oxide devices, such as amorphous IGZO (a-IGZO) thin film transistors, and methods for forming such devices. In some embodiments, a relatively thin (e.g., about 10 nanometers (nm)) a-IGZO channel is utilized. In some embodiments, a plasma treatment chemical precursor (e.g., a fluorine-containing gas) passivation is provided to the front-side a-IGZO interface. In some embodiments, high-k dielectric materials are used in the etch-stop layer at the back-side a-IGZO interface. In some embodiments, a barrier layer (e.g., including tantalum or titanium) is formed above the gate electrode before the gate dielectric layer is deposited. In some embodiments, the conventional etch-stop layer, typically formed before the source and drain regions are defined, is replaced by a pre-passivation layer that is formed after the source and drain regions are defined, includes fluorine, and may include multiple sub-layers.

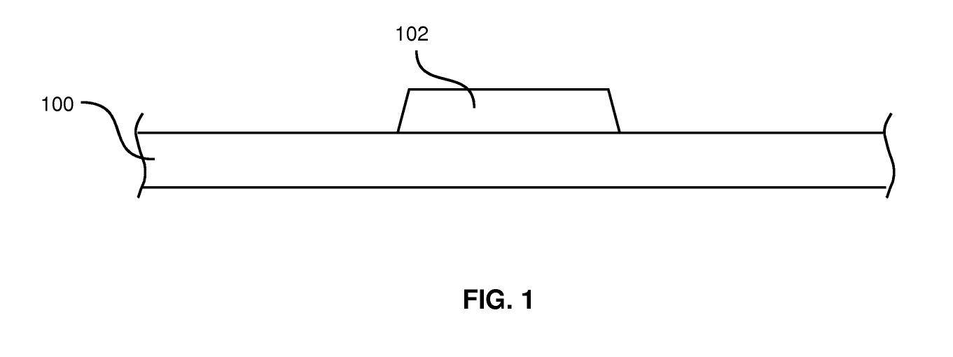

FIGS. 1-8 illustrate a method for forming an a-IGZO thin film transistor (or more generically, an IGZO device), according to some embodiments of the present invention.

Referring now to FIG. 1, a substrate 100 is shown. In some embodiments, the substrate 100 is transparent and is made of, for example, glass. The substrate 100 may have a thickness of, for example, between 0.1 and 2.0 centimeters (cm). Although only a portion of the substrate 100 is shown, it should be understood that the substrate 100 may have a width of, for example, between 5.0 cm and 2.0 meters (m).

Still referring to FIG. 1, a gate electrode 102 is formed above the transparent substrate 100. In some embodiments, the gate electrode 102 is made of a conductive material, such as copper, and has a thickness of, for example, between about 30 nm and about 300 nm. It should be understood that the various components on the substrate, such as the gate electrode 102 and those described below, are formed using processing techniques suitable for the particular materials being deposited, such as physical vapor deposition (PVD) (e.g., co-sputtering in some embodiments), chemical vapor deposition (CVD), electroplating, etc. Furthermore, although not specifically shown in the figures, it should be understood that the various components on the substrate 100, such as the gate electrode 102, may be sized and shaped using a photolithography process and an etching process, as is commonly understood, such that the components are formed above selected regions of the substrate 100.

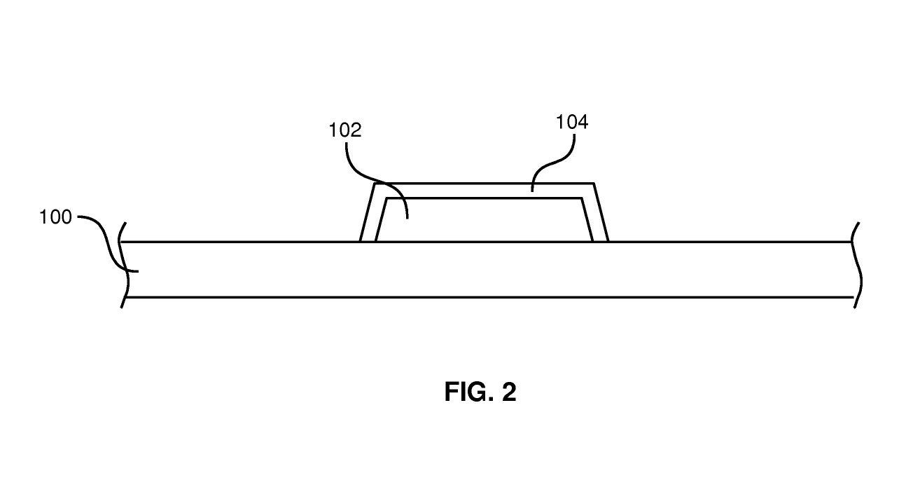

As shown in FIG. 2, a gate electrode barrier layer 104 is formed above the gate electrode 102 to cover the entire gate electrode 102, including the sides thereof (e.g., via conformal deposition). In some embodiments, the gate electrode barrier layer 104 includes tantalum, titanium, or a combination thereof. The gate electrode barrier layer 104 may also include silicon and/or may be a nitride. Exemplary materials include tantalum-silicon nitride, tantalum nitride, tantalum, titanium nitride, and combinations thereof. In some embodiments, the gate barrier layer 104 has a thickness of, for example, between about 0.1 nm and about 5.0 nm. It should be noted that the gate electrode barrier layer 104 may be considered to be a portion of the gate electrode 102.

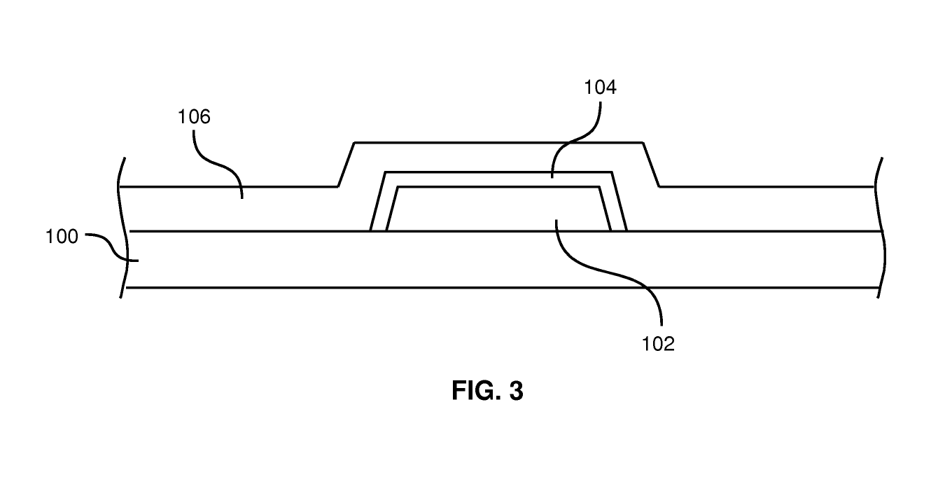

Referring to FIG. 3, a gate dielectric layer 106 is then formed above the gate electrode barrier layer 104 and the exposed portions of the substrate 100. The gate dielectric layer 106 may be made of a high-k dielectric (e.g., having a dielectric constant greater than 3.9), such as zirconium oxide, hafnium oxide, or aluminum oxide. In some embodiments, the gate dielectric layer 106 has a thickness of, for example, between about 30 nm and about 100 nm.

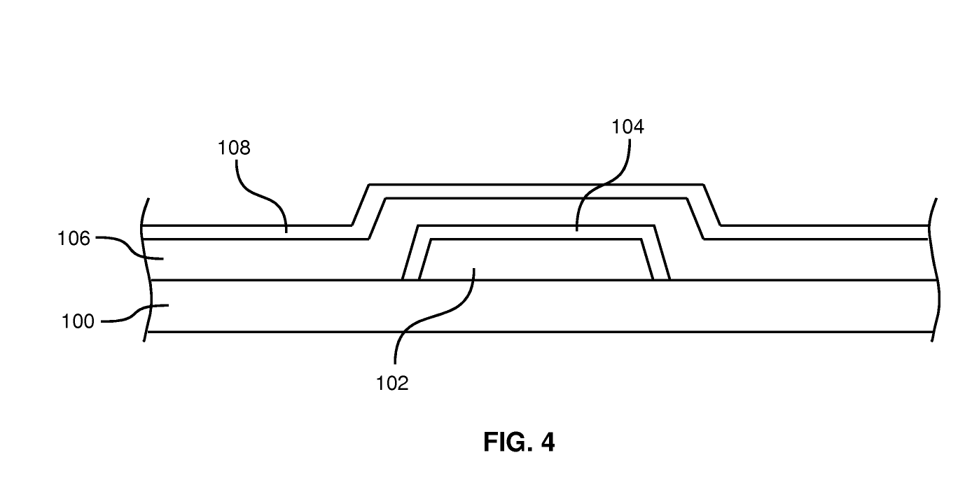

In some embodiments, an interfacial dielectric layer (or gate dielectric barrier layer) 108 is then formed above the gate dielectric layer 106, as shown in FIG. 4. In some embodiments, the interfacial dielectric layer 108 is made of silicon oxide and has a thickness of, for example, between about 0.2 nm and about 5.0 nm. It should be noted that the interfacial dielectric layer 108 may be considered to be a portion of the gate dielectric layer 106.

In some embodiments, before the formation of the IGZO channel layer (described below), the upper surface of the interfacial dielectric layer 108 is exposed to a fluorine-containing gas to perform a fluoride passivation to the interfacial dielectric layer 108. The fluorine-containing gas may include a xenon fluoride (XeF₂₋₆), nitrogen fluoride, carbon fluoride, or a combination thereof. In some embodiments, such as describe below, the interfacial dielectric layer 108 is omitted, and in such embodiments, the upper surface of the gate dielectric layer 106 may be exposed to the fluorine-containing gas before the formation of the IGZO channel layer.

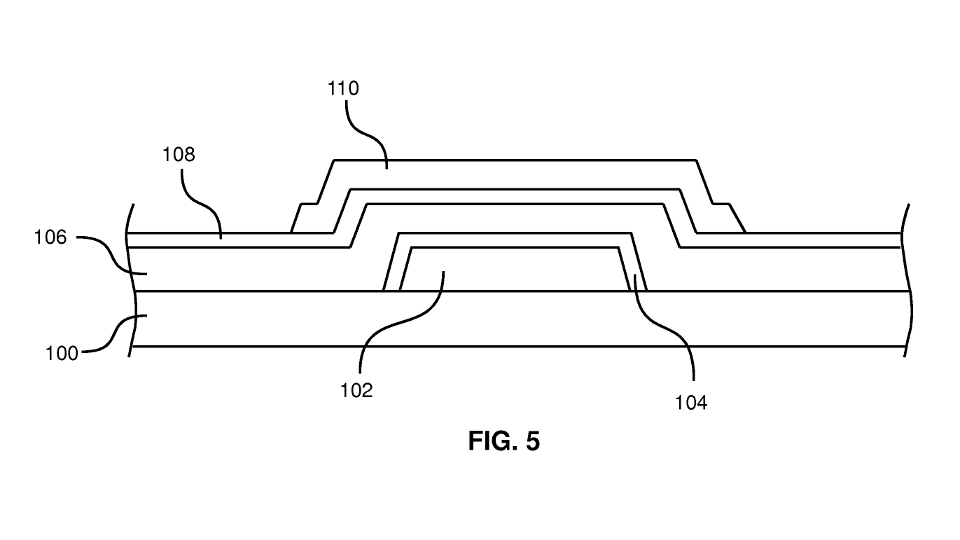

As shown in FIG. 5, an IGZO channel layer (or active layer) 110 is then formed above the interfacial dielectric layer 108, over the gate electrode 102. The IGZO channel layer 110 is made of, for example, amorphous indium-gallium-zinc oxide in which a ratio of the respective elements is 1:1:1:1-3. The IGZO channel layer 110 may have a thickness of, for example, between about 5 nm and about 50 nm, preferably between about 5 nm and about 15 nm (e.g., about 10 nm).

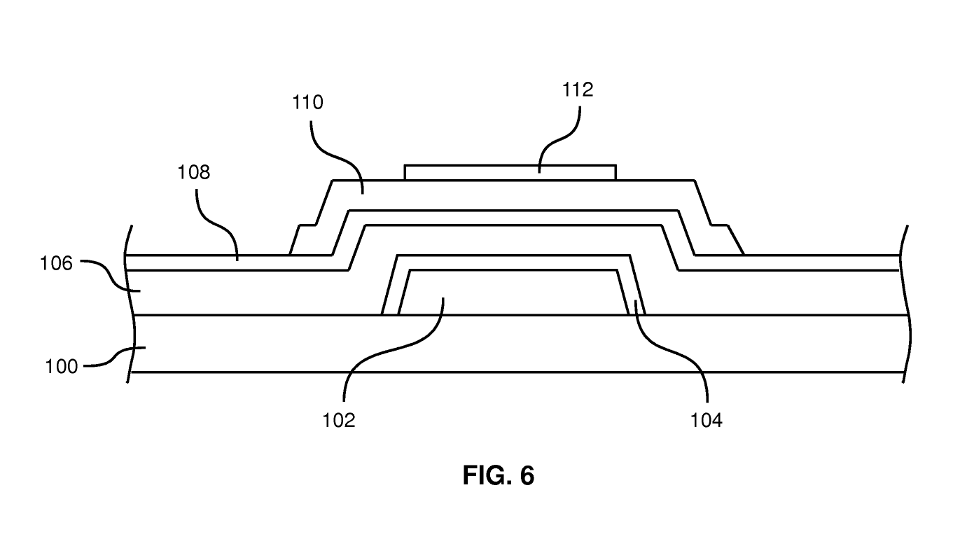

Referring now to FIG. 6, an etch-stop layer 112 is then formed above the IGZO channel layer 110. In some embodiments, the etch-stop layer is made of a high-k dielectric, such as aluminum oxide and/or hafnium oxide. The etch-stop layer may have a thickness of, for example, between about 20 nm and about 100 nm. In some embodiments, such as described below, the etch-stop layer 112 includes multiple sub-layers, such as a first sub-layer made of the high-k dielectric and a second sub-layer (formed above the first sub-layer) made of fluorinated silicate glass (FSG).

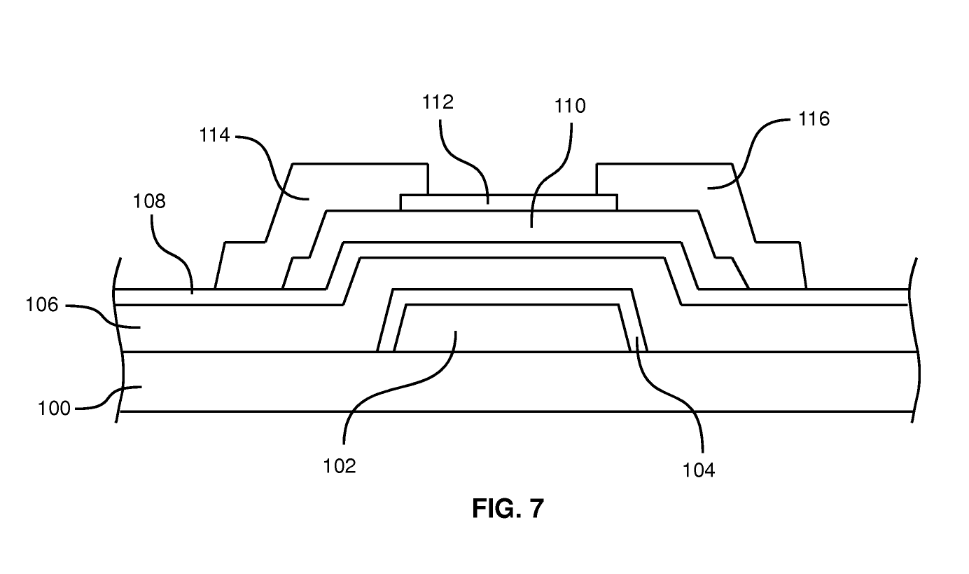

Next, as shown in FIG. 7, a source region (or electrode) 114 and a drain region 116 are formed above the IGZO channel layer 110 and the interfacial dielectric layer 108. As shown, the source region 114 and the drain region 116 lie on opposing sides of, and partially overlap the ends of, the etch-stop layer 112. In some embodiments, the source region 114 and the drain region 116 are made of titanium, molybdenum, copper, copper-manganese alloy, or a combination thereof. The source region 114 and the drain regions 116 may have a thickness of, for example, between about 50 nm and 0.5 micrometers (μm).

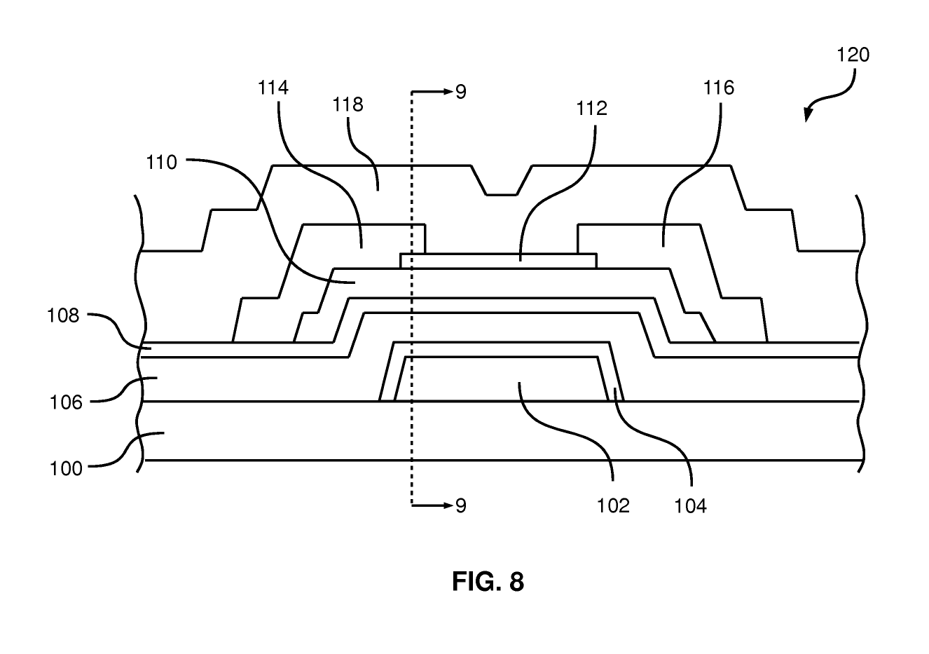

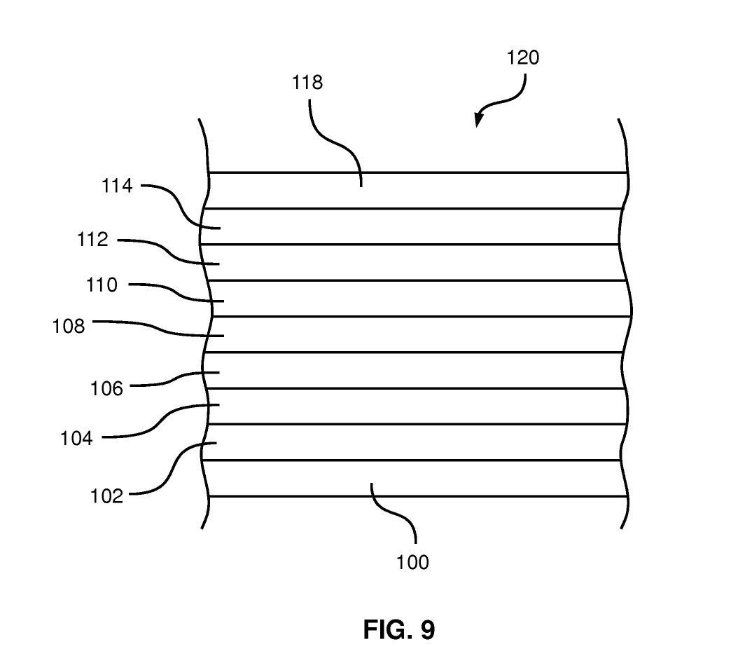

Referring to FIG. 8, a passivation layer 118 is then formed above the source region 114, the drain region 116, the etch-stop layer 112, and the interfacial dielectric layer 108. In some embodiments, the passivation layer 118 is made of silicon oxide, silicon nitride, or a combination thereof and has a thickness of, for example, between about 0.1 μm and about 1.5 μm. The deposition of the passivation layer 118 may substantially complete the formation of an IGZO device 120, such as an inverted, staggered bottom-gate a-IGZO TFT. It should be understood that although only a single device 120 is shown as being formed on a particular portion of the substrate 100 in FIGS. 1-8, the manufacturing processes described above may be simultaneously performed on multiple portions of the substrate 100 such that multiple devices 120 are simultaneously formed, as is commonly understood. FIG. 9 illustrates a view of the IGZO device 120 taken along line 9-9 in FIG. 8.

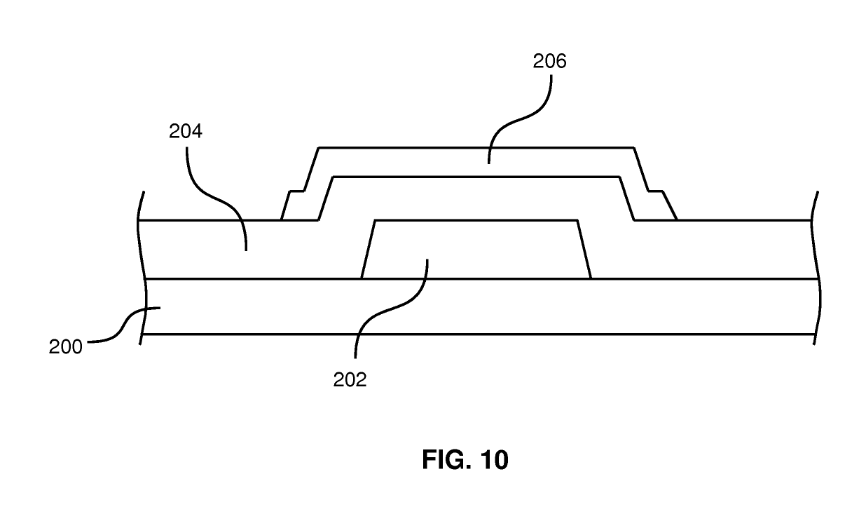

FIGS. 10-13 illustrate a method for forming an a-IGZO thin film transistor (or more generically, an IGZO device), according to some embodiments of the present invention.

Referring to FIG. 10, a substrate 200 is shown. In some embodiments, the substrate 200 is transparent and is made of, for example, glass. The substrate 200 may have a thickness of, for example, between 0.1 and 2.0 centimeters (cm). Although only a portion of the substrate 100 is shown, it should be understood that the substrate 200 may have a width of, for example, between 5.0 cm and 2.0 meters (m).

Still referring to FIG. 10, a gate electrode 202, a gate dielectric layer 204, and an IGZO channel layer 206 are formed above the substrate 200. In some embodiments, the gate electrode 202 is made of a conductive material, such as copper, and has a thickness of, for example, between about 0.1 μm and about 1.0 μm. The gate dielectric layer 204 is formed above the gate electrode 202 and the exposed portions of the substrate 200. The gate dielectric layer 204 may be made of a dielectric material, such as silicon oxide. In some embodiments, the gate dielectric layer 204 has a thickness of, for example, between about 30 nm and about 200 nm.

In some embodiments, before the formation of the IGZO channel layer 206, the upper surface of the gate dielectric layer 204 is exposed to a fluorine-containing gas to perform a fluoride passivation to the gate dielectric layer 204. The fluorine-containing gas may include a xenon fluoride (XeF₂₋₆), nitrogen fluoride, carbon fluoride, or a combination thereof.

The IGZO channel layer (or active layer) 206 is formed above the gate dielectric layer 204, over the gate electrode 202. The IGZO channel layer 206 is made of, for example, amorphous indium-gallium-zinc oxide in which a ratio of the respective elements is 1:1:1:1-3. The IGZO channel layer 206 may have a thickness of, for example, between about 10 nm and about 50 nm.

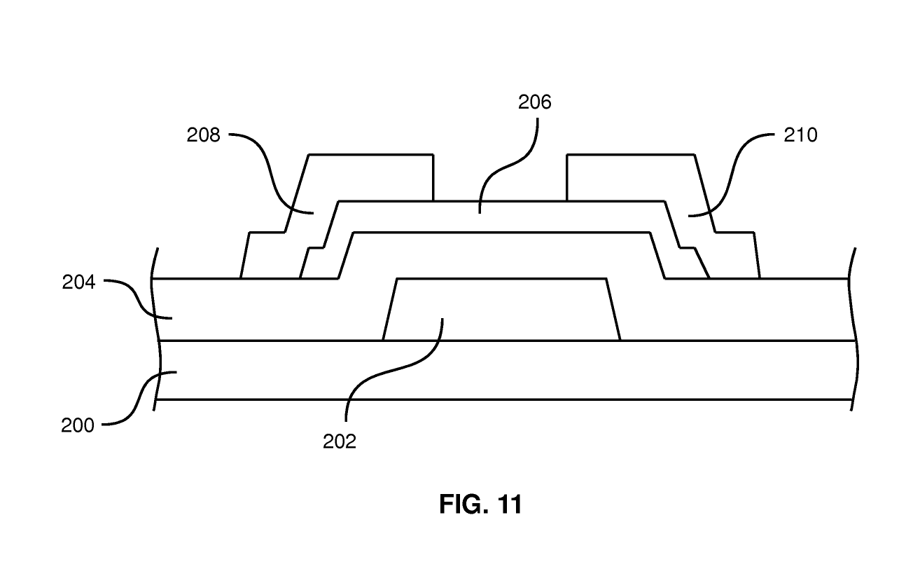

As shown in FIG. 11, a source region (or electrode) 208 and a drain region 210 are then formed above the IGZO channel layer 206 and the gate dielectric layer 204. In some embodiments, the source region 208 and the drain region 210 are formed with a gap between, which is centered over the gate electrode 202. In some embodiments, the source region 208 and the drain region 210 are made of titanium, molybdenum, copper, copper-manganese alloy, or a combination thereof. The source region 208 and the drain region 210 may have a thickness of, for example, between about 50 nm and 0.5 micrometers (μm).

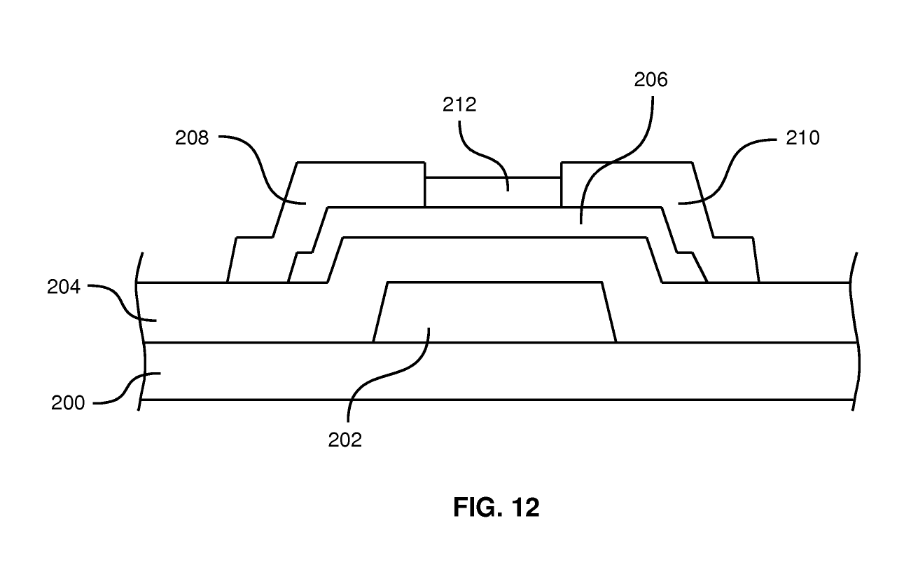

Referring to FIG. 12, a pre-passivation layer (or etch-stop layer) 212 is then formed above the IGZO channel layer 206 and between the source region 208 and the drain region 210. It should be noted that in such embodiments, the pre-passivation layer 212 is formed after the source region 208 and the drain region 210. In some embodiments, the pre-passivation layer 212 is made of a high-k dielectric (e.g., aluminum oxide and/or hafnium oxide), silicon oxide, fluorinated silicate glass (FSG), or a combination thereof. However, in some embodiments, the pre-passivation layer 212 includes multiple sub-layers, as is described in greater detail below.

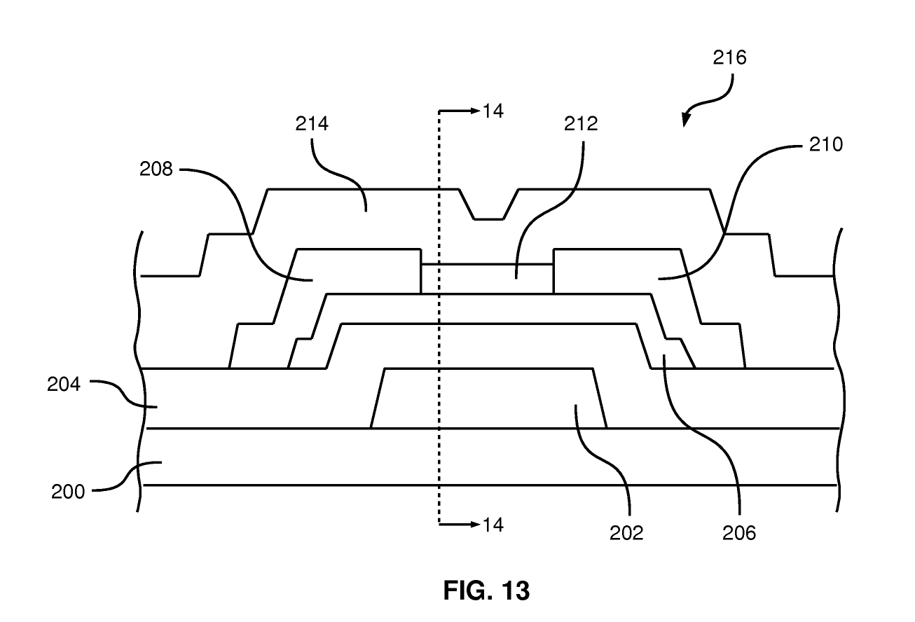

As shown in FIG. 13, a passivation layer 214 is then formed above the source region 208, the drain region 210, the pre-passivation layer 212, and the gate dielectric layer 204. In some embodiments, the passivation layer 214 is made of silicon oxide, silicon nitride, or a combination thereof and has a thickness of, for example, between about 0.1 μm and about 1.5 μm. The deposition of the passivation layer 214 may substantially complete the formation of an IGZO device 216, such as an inverted, staggered bottom-gate a-IGZO TFT. As is commonly understood, the processing steps described above may be simultaneously performed on multiple portions of the substrate 200 so that multiple devices 216 are simultaneously formed.

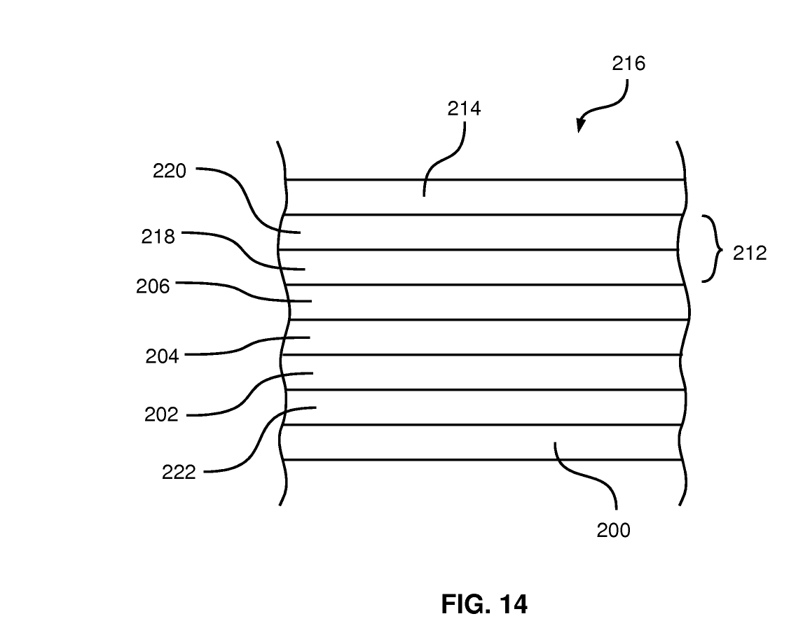

FIG. 14 illustrates a view of the IGZO device taken along line 14-14 in FIG. 13. Of particular interest in FIG. 14 is that the pre-passivation layer 212 includes a first sub-layer 218 (formed above the IGZO channel layer 206) and a second sub-layer 220 (formed above the first sub-layer 218). In some embodiments, the first sub-layer 218 is made of a high-k dielectric (e.g., aluminum oxide and/or hafnium oxide), silicon oxide, or a combination thereof, and the second sub-layer 220 is made of FSG. In some embodiments, the FSG is deposited using a carbon fluoride precursor. The FSG may also undergo a fluorine ambient annealing process in a gaseous environment including, for example, fluorine gas and argon gas (e.g., 0.3% F₂ and 99.7% Ar) at 400-450° C. for about 10-30 minutes.

As also shown in FIG. 14, in some embodiments, a seed layer 222 is formed between the substrate 200 and the gate electrode 202. In some embodiments, the seed layer 222 includes copper and has a thickness of, for example, between about 1 nm and about 5 nm. The seed layer 222 may be made of copper-manganese alloy (e.g., 96-99% copper and 1-4% manganese).

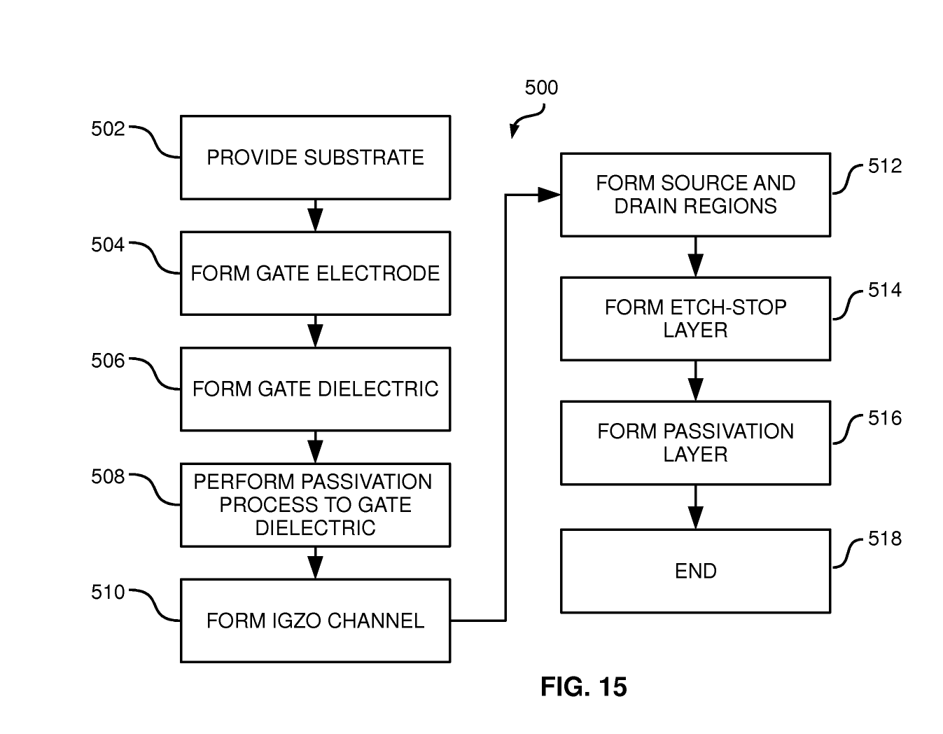

FIG. 15 illustrates a method 500 for forming an IGZO device, such as an a-IGZO TFT, according to some embodiments, such as those described above. At block 502, the method begins with a substrate, such as a glass substrate, being provided.

At block 504, a gate electrode is formed above the substrate. In some embodiments, the gate electrode is made of copper. The formation of the gate electrode may include the deposition of a seed layer before the deposition of the primary gate electrode material (e.g., copper). In some embodiments, the seed layer is made of a copper-manganese alloy. Additionally, in some embodiments, the formation of the gate electrode may include the formation of a gate electrode barrier layer above the primary gate electrode material. The gate electrode barrier layer may be made of tantalum-silicon nitride, tantalum nitride, tantalum, titanium nitride, or a combination thereof.

At block 506, a gate dielectric (or gate dielectric layer) is formed above the gate electrode. In some embodiments, the gate dielectric is made of a high-k dielectric material (e.g., zirconium oxide, hafnium oxide, aluminum oxide, etc.), silicon oxide, or a combination thereof. In some embodiments, in which a high-k dielectric material is used, the formation of the gate dielectric may include the formation of an interfacial dielectric layer is formed above the primary gate dielectric material (e.g., zirconium oxide). The interfacial dielectric layer may be made of silicon oxide.

At block 508, in some embodiments, the upper surface of the gate dielectric (e.g., the upper surface of the interfacial dielectric layer) is exposed to a fluorine-containing gas to perform a fluoride passivation. The fluorine-containing gas may include a xenon fluoride (XeF₂₋₆), nitrogen fluoride, carbon fluoride, or a combination thereof. At block 510, an IGZO channel (or channel layer) is formed above the gate dielectric. The IGZO channel may be made of a-IGZO.

In some embodiments, at block 512, source and drain regions are then formed (or defined) above the IGZO channel, and at block 514, an etch-stop (or pre-passivation) layer is formed at least partially between the source region and the drain region. It should be noted that in some embodiments, the pre-passivation layer is formed after the formation of the source and drain regions. In such embodiments, the pre-passivation layer may include multiple sub-layers and a fluorine-containing material (e.g., FSG). However, in some embodiments, an etch-stop layer is formed before the formation of the source and drain regions. In such embodiments, the etch-stop layer may be made of a high-k dielectric, such as hafnium oxide and/or aluminum oxide.

At block 516, a passivation layer is then formed above the source and drain regions and the etch-stop layer. In some embodiments, the passivation layer is made of silicon nitride. At block 518, the method 500 ends with the completion (or substantial completion) of an IGZO device, such as an inverted, staggered bottom-gate a-IGZO TFT.

The embodiments described may improve upon conventional a-IGZO TFTs in various ways. One example is the use of a relatively thin a-IGZO channel layer (e.g., at a thickness of about 10 nm). As the thickness of the a-IGZO channel layer is reduced, the ON current (I_{ON}) in the accumulated channel (i.e., the gate-to-source voltage (V_{GS}) is greater than the flat-band voltage (V_{FB})) increases while the OFF current (IOFF) in the inverted channel (i.e., V_{GS}<V_{FB}) decreases. Moreover, the physically thinner a-IGZO provides a thicker accumulated channel during the on-state. Since electron current in the off-state mostly flows at the surface of the back-side interface, the OFF current can be lower when the front-side channel is inverted more with holes under the same bias and temperature conditions.

Another example is the chemical passivation (e.g., the exposure to the fluorine-containing gas(es)) at the front-side a-IGZO interface. A further example is the use of the high-k dielectric materials (e.g., hafnium oxide and/or aluminum oxide) in the etch-stop layer, which may reduce the interface trap density (Dit) at the back-side IGZO interface, as well as the OFF current. Moreover, by using wide band-gap material(s) at the back-side, the threshold voltage variation (ΔV_{TH}) may also be reduced. Furthermore, the addition of a fluorine-containing layer/sub-layer (e.g., FSG) over the high-k dielectric material may cause fluorine to diffuse toward the back-side interface for effective interface passivation.

The gate electrode barrier layer may prevent copper from diffusing into the gate dielectric, and perhaps even into the a-IGZO channel layer. In applications in which electro-migration reliability is a concern for high gate voltage electrodes (e.g., greater than 30 V), the seed layer may be deposited before the formation of the gate electrode. The use of the pre-passivation layer formed after the source and drain regions are defined may reduce overall manufacturing costs when compared to a convention etch-stop layer formed using a back-channel-etch (BCE) process.

Thus, in some embodiments, a method for forming an IGZO device is provided. A substrate is provided. A gate electrode is formed above the substrate. A gate dielectric layer is formed above the gate electrode. The gate dielectric layer is exposed to a fluorine-containing gas to perform a fluoride passivation to the gate dielectric layer. An a-IGZO channel layer is formed above the gate dielectric layer. Source and drain regions are formed above the IGZO layer.

In some embodiments, a method for forming an IGZO device is provided. A substrate is provided. A gate electrode is formed above the substrate. A gate dielectric layer is formed above the gate electrode. An a-IGZO channel layer is formed above the gate dielectric layer. Source and drain regions are formed above the IGZO channel layer. An etch-stop layer is formed above the IGZO channel layer and at least partially between the source and drain regions. The etch-stop layer includes aluminum oxide, hafnium oxide, or a combination thereof.

In some embodiments, a method for forming an IGZO device is provided. A substrate is provided. A gate electrode is formed above the substrate. The gate electrode includes copper. A barrier layer is formed above the gate electrode. The barrier layer includes tantalum, titanium, or a combination thereof. A gate dielectric layer is formed above the barrier layer. An a-IGZO channel layer is formed above the gate dielectric layer. Source and drain regions are formed above the IGZO channel layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a device, the method comprising:
providing a substrate;
forming a gate electrode above the substrate;
forming a gate dielectric layer above the gate electrode;
exposing the gate dielectric layer to a fluorine-containing gas;
forming an IGZO channel layer above the gate dielectric layer; and
forming source and drain regions above the IGZO channel layer.

2. The method of claim 1, wherein the gate dielectric layer comprises a high-k dielectric material.

3. The method of claim 2, further comprising forming a silicon oxide interfacial layer above the gate dielectric layer before the forming of the IGZO channel layer.

4. The method of claim 2, wherein the gate dielectric layer comprises zirconium oxide, hafnium oxide, or a combination thereof.

5. The method of claim 1, wherein the fluorine-containing gas comprises a xenon fluoride, nitrogen fluoride, carbon fluoride, or a combination thereof.

6. The method of claim 1, further comprising forming an etch-stop layer above the IGZO channel layer and at least partially between the source region and the drain region, wherein the etch-stop layer comprises aluminum oxide, hafnium oxide, or a combination thereof.

7. The method of claim 1, wherein the IGZO channel layer has a thickness between about 5 nanometers (nm) and 15 nm.

8. A method for forming a device, the method comprising:
providing a substrate;
forming a gate electrode above the substrate;
forming a gate dielectric layer above the gate electrode;
forming an IGZO channel layer above the gate dielectric layer;
forming source and drain regions above the IGZO channel layer; and
forming an etch-stop layer above the IGZO channel layer and at least partially between the source and drain regions, wherein the etch-stop layer comprises aluminum oxide, hafnium oxide, or a combination thereof.

9. The method of claim 8, further comprising exposing the gate dielectric layer to a fluorine-containing gas before the forming of the IGZO channel layer.

10. The method of claim 8, further comprising forming a silicon oxide interfacial layer above the gate dielectric layer before the forming of the IGZO channel layer.

11. The method of claim 8, wherein the etch-stop layer comprises a first sub-layer formed above the IGZO channel layer and a second sub-layer formed above the first sub-layer.

12. The method of claim 11, wherein the first sub-layer of the etch-stop layer comprises aluminum oxide, hafnium oxide, or a combination thereof, and the second sub-layer comprises fluorinated silicate glass.

13. The method of claim 8, wherein the IGZO channel layer has a thickness between about 5 nanometers (nm) and 15 nm.

14. The method of claim 8, further comprising forming a barrier layer above the gate electrode before the forming of the gate dielectric layer, wherein the barrier layer comprises tantalum-silicon nitride, tantalum nitride, tantalum, titanium nitride, or a combination thereof.

15. A method for forming an indium gallium zinc oxide (IGZO) device, the method comprising:
providing a substrate;
forming a gate electrode above the substrate, wherein the gate electrode comprises copper;
forming a barrier layer above the gate electrode, wherein the barrier layer comprises tantalum, titanium, or a combination thereof;
forming a gate dielectric layer above the barrier layer;
forming an IGZO channel layer above the gate dielectric layer; and
forming source and drain regions above the IGZO channel layer.

16. The method of claim 15, further comprising exposing the gate dielectric layer to a fluorine-containing gas before the forming of the IGZO channel layer.

17. The method of claim 15, further comprising forming an etch-stop layer above the IGZO channel layer and at least partially between the source and drain regions.

18. The method of claim 17, wherein the etch-stop layer comprises aluminum oxide, hafnium oxide, or a combination thereof.

19. The method of claim 17, wherein the etch-stop layer comprises a first sub-layer formed above the IGZO channel layer and a second sub-layer formed above the first sub-layer, wherein the first sub-layer of the etch-stop layer comprises silicon oxide, and the second sub-layer comprises fluorinated silicate glass.

20. The method of claim 19, further comprising forming a silicon oxide interfacial layer above the gate dielectric layer before the forming of the IGZO channel layer.
